(19) United States
(12) Patent Application Publication
(10) Pub. No.: US 2025/0336710 A1
(43) Pub. Date: Oct. 30, 2025

(54) LIFT PINS TO FACILITATE UNIFORMITY, AND RELATED COMPONENTS, CHAMBER KITS, PROCESSING CHAMBERS, AND METHODS

(71) Applicant: Applied Materials, Inc., Santa Clara, CA (US)

(72) Inventors: Zhepeng CONG, San Jose, CA (US); Benjamin Ean THAM, Elk Grove, CA (US)

(21) Appl. No.: 18/647,984

(22) Filed: Apr. 26, 2024

(51) Int. Cl. H01L 21/687

(52) U.S. Cl. CPC H01L 21/68742

(57) ABSTRACT

The present disclosure relates to lift pins that facilitate uniformity, and related components, chamber kits, processing chambers, and methods for semiconductor manufacturing. In one or more embodiments, a lift pin for processing chambers includes a rod including a shaft section and a head section. The head section includes an opening formed in an outer edge of the head section and extending radially inwardly. The lift pin includes a pad sized and shaped to fit at least partially around the head section of the rod such that the head section of the rod is movable relative to the pad within a movement range.

### BACKGROUND

### Field

The present disclosure relates to lift pins that facilitate uniformity, and related components, chamber kits, processing chambers, and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

During processing, various parameters can affect the uniformity of material deposited on the substrate. For example, the temperature of the substrate and/or temperature(s) of processing chamber component(s) can affect deposition uniformity. As another example, temperature differences (such as temperature gradients) in processing chambers can affect film deposition uniformity, concentration uniformity, and/or site-front-least-squares-range (e.g., warpage uniformity), which can hinder device performance and reduce throughput. Moreover, operations can degrade components (causing lower lifespans) and can cause thermal shock.

Therefore, a need exists for improved chamber components that facilitate temperature uniformities.

### SUMMARY

The present disclosure relates to lift pins that facilitate uniformity, and related components, chamber kits, processing chambers, and methods for semiconductor manufacturing.

In one or more embodiments, a lift pin for a processing chamber includes a rod including a shaft section and a head section. The head section includes an opening formed in an outer edge of the head section and extending radially inwardly. The lift pin includes a pad sized and shaped to fit at least partially around the head section of the rod such that the head section of the rod is movable relative to the pad within a movement range.

In one or more embodiments, a pad for a lift pin includes a head section and a sleeve section. The sleeve section extends relative to the head section, and the sleeve section includes a pad opening formed in an end face of the sleeve section. The pad opening extends radially inward into an outer face of the sleeve section.

In one or more embodiments, a processing chamber applicable for use in semiconductor manufacturing includes a substrate support disposed in a processing volume of the processing chamber, and a plurality of lift pins disposed at least partially through the substrate support. At least one of the plurality of lift pins include a pad including a pad opening formed in an end face of the pad, and a rod disposed at least partially in the pad opening of the pad. The rod includes a shaft section and a head section. The head section includes an opening formed in an outer edge and an end face of the head section.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic perspective view of a plurality of lift pins disposed at least partially through the substrate support shown in FIG. 1, according to one or more embodiments.

FIG. 3 is a schematic perspective view of the plurality of lift pins shown in FIG. 2, according to one or more embodiments

FIG. 4 is a schematic side view of one of the lift pins shown in FIGS. 2 and 3 in an unlocked position, according to one or more embodiments.

FIG. 5 is a schematic side view of one of the lift pins shown in FIG. 4 in a locked position, according to one or more embodiments.

FIG. 6 is a schematic side view of the one of the lift pins in the unlocked position shown in FIG. 4, according to one or more embodiments.

FIG. 7 is a schematic side view of the one of the lift pins in the locked position shown in FIG. 5, according to one or more embodiments.

FIG. 8 is a schematic side view of the one of the lift pins, along Section 8-8, in the unlocked position shown in FIG. 6, according to one or more embodiments.

FIG. 9 is a schematic side view of the one of the lift pins, along Section 9-9, in the locked position shown in FIG. 7, according to one or more embodiments.

FIG. 10 is a schematic side view of one of the lift pins shown in FIGS. 2 and 3 in an unlocked position, according to one or more embodiments.

FIG. 11 is a schematic side view of one of the lift pins shown in FIG. 4 in a locked position, according to one or more embodiments.

FIG. 12 is a schematic side view of the one of the lift pins in the unlocked position shown in FIG. 10, according to one or more embodiments.

FIG. 13 is a schematic side view of the one of the lift pins in the locked position shown in FIG. 11, according to one or more embodiments.

FIG. 14 is a schematic side view of one of the lift pins shown in FIGS. 2 and 3 in an unlocked position, according to one or more embodiments.

FIG. 15 is a schematic side view of one of the lift pins in the locked position shown in FIG. 14, according to one or more embodiments.

FIG. 16 is a schematic graph illustrating substrate temperature versus distance (in mm) for a substrate aligned above a lift pin according to a configuration other than those described herein.

FIG. 17 is a top graphical view of substrate film thickness according to a configuration other than those described herein.

FIG. 18 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to lift pins that facilitate uniformity, and related components, chamber kits, processing chambers, and methods for semiconductor manufacturing.

The disclosure contemplates that terms such as “couples,” “coupling,” “couple,” and “coupled” may include but are not limited to bonding, embedding, welding, fusing, melting together, interference fitting, threading, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

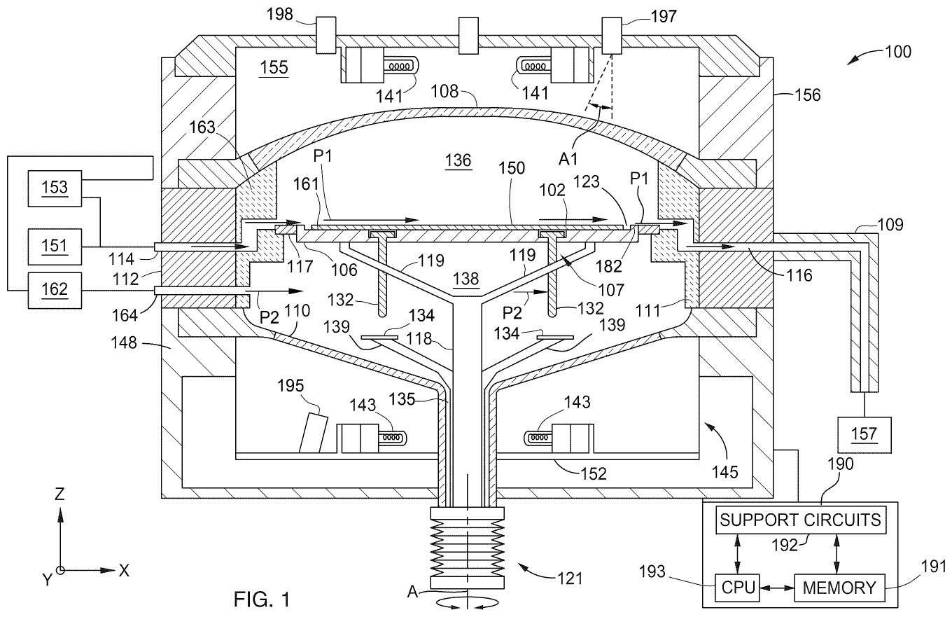

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window, for example an upper dome), a lower plate 110 (such as a lower window, for example a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate 108 and a lid 154. The plurality of upper heat sources 141 form a portion of the upper heat source module 155.

The plurality of lower heat sources 143 are disposed between the lower plate 110 and a floor 152. The plurality of lower heat sources 143 form a portion of a lower heat source module 145. In one or more embodiments, the upper plate 108 is an upper dome and/or is formed of an energy transmissive material, such as quartz. The lower plate 110 is a lower dome and/or is formed of an energy transmissive material, such as quartz.

A processing volume 136 and a purge volume 138 are formed between the upper plate 108 and the lower plate 110. The processing volume 136 and the purge volume 138 are part of an internal volume defined at least partially by the upper plate 108, the lower plate 110, and one or more liners 111, 163. In one or more embodiments, the processing volume 136 is a processing volume. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

A plurality of lift pins 132 are disposed at least partially through the substrate support 106. The substrate support 106 may include lift pin holes 107 disposed therein. The lift pin holes 107 are each sized to accommodate a lift pin 132 of the plurality of lift pins 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 111, 163. As an example, one or more sensor devices 195, 196, 197, 198 can measure temperatures and power to the heat sources 141, 143 can be controlled based on the measured temperatures (e.g., using a feedback control). As described the one or more sensor devices can include, for example pyrometers. In one or more embodiments, one or more thermocouples (e.g., proximity thermocouples) are disposed to measure temperatures and power to the one or more heat sources 141, 143 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 141, 143, the deposition, the cleaning, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump 157.

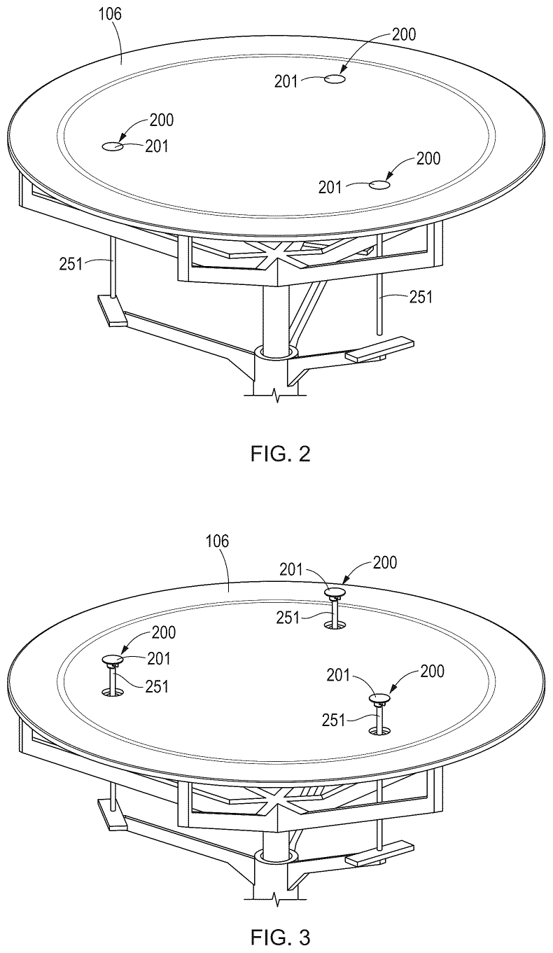

FIG. 2 is a schematic perspective view of a plurality of lift pins 200 disposed at least partially through the substrate support 106 shown in FIG. 1, according to one or more embodiments. Three lift pins 200 are shown in FIG. 2.

The lift pins 200 respectively include a rod 251 and a pad 201 fitted at least partially around the rod 251. The plurality of lift pins 200 are spaced from each other long a geometric pattern. As shown in FIG. 2, the geometric pattern is a triangular pattern. Other geometric patterns are contemplated. As shown in FIG. 2, the rods 251 of the plurality of lift pins 200 are oriented parallel to each other. FIG. 2 shows the lift pins 200 in a lowered position, such as a processing position. The processing position can be used, for example, when a substrate supported by the substrate support 106 is processed (such as etched or deposited upon), and/or when the substrate support 106 is cleaned.

FIG. 3 is a schematic perspective view of the plurality of lift pins 200 shown in FIG. 2, according to one or more embodiments. FIG. 3 shows the lift pins 200 in a raised position, such as a transfer position where the lift pins 200 raise a substrate off of the substrate support 106 to transfer the substrate out of the processing chamber 100. By raising and lowering the shaft 135, the lift pin stops 134 can raise and lower the lift pins 200 between the raised position and the lowered position.

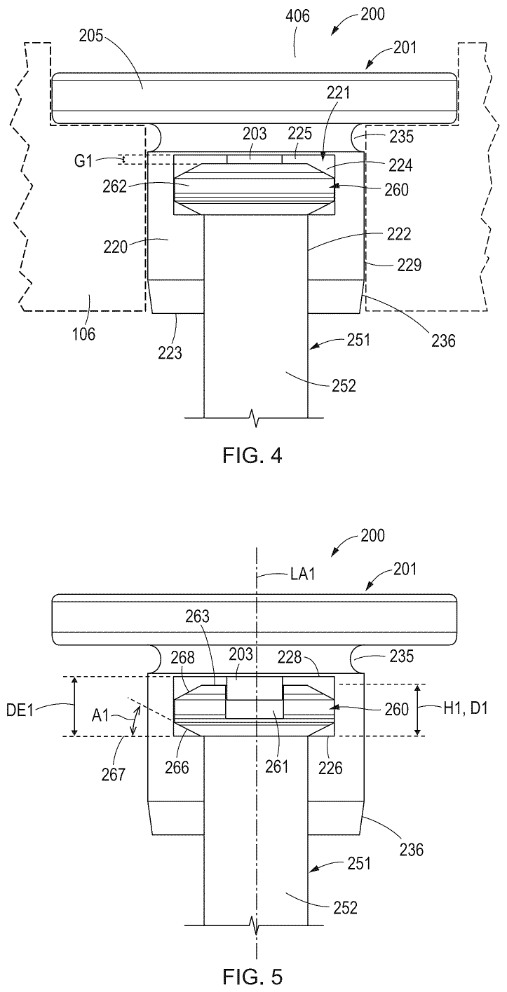

FIG. 4 is a schematic side view of one of the lift pins 200 shown in FIGS. 2 and 3 in an unlocked position, according to one or more embodiments.

FIG. 5 is a schematic side view of one of the lift pins 200 shown in FIG. 4 in a locked position, according to one or more embodiments.

FIGS. 4 and 5 are described together. The lift pin 200 is movable (e.g., rotatable) between the unlocked position shown in FIG. 4 and the locked position shown in FIG. 5. One or more of the pad 201 or the rod 251 are rotatable with respect to each other between the unlocked position and the locked position. The lift pin 200 can be used as at least one of the lift pins 132 shown in FIG. 1. In the unlocked position, the pad 201 can be removed from the rod 251, the rod 251 can be re-used, and a subsequent pad 201 can be locked to the rod 251 for reduced operating costs.

The rod 251 of the lift pin 200 includes a shaft section 252 and a head section 260. The head section 260 includes an opening 261 (e.g., a rod opening) formed in an outer edge 262 of the head section 260 and extending radially inwardly, such as toward a center of the head section 260. In one or more embodiments, the opening 261 includes a slot extending into an end face 263 of the head section 260 of the rod 251. The pad 201 includes a protrusion 203 sized and shaped to protrude into the opening 261 (e.g., the slot) of the head section 260. The pads 201 of the lift pins 200 contact and support the substrate 102 during substrate transfer.

The pad 201 is sized and shaped to fit at least partially around the head section 260 of the rod 251 such that the head section 260 of the rod 251 is movable relative to the pad 201. The pad 201 includes a head section 205 and a sleeve section 220 extending relative to a side of the head section 205. The sleeve section 220 includes a pad opening 221. The pad opening 221 includes a first section 222 formed in an end face 223 of the sleeve section 220, and a second section 224 between the first section 222 and the head section 205 of the pad 201. The sleeve section 220 includes an outer recess 235 (such as an outer groove) and a tapered out surface 236 to facilitate ease of positioning and fitting into an opening 406 of the substrate support 106. The second section 224 has a larger dimension (such as a larger diameter) than the first section 222. The protrusion 203 of the pad 201 extends into the second section 224 to define an annular channel 225 at least partially about the protrusion 203. The first section 222 and the second section 224 extend radially inward into an outer face 229 of the sleeve section 220.

The head section 260 of the rod 251 includes a tapered outer surface 266 sized and shaped to interface with a first inner surface 226 of the sleeve section 220. The present disclosure contemplates that the taper of the tapered outer surface 266 can be linear (as shown) and/or curved (such as rounded). The taper of the tapered outer surface 266 has a taper angle A1 within a range of 10 degrees to 40 degrees. The taper angle A1 can be relative to a plane 267 perpendicular to a longitudinal axis LA1 of the rod 251. In one or more embodiments, the taper angle A1 is within a range of 15 degrees to 30 degrees. In one or more embodiments, the taper angle A1 is within a range of 20 degrees to 25 degrees, such as about 22.5 degrees. One or more of the pad 201 or the rod 251 are rotatable in a plane (such as the plane 267) oriented at an angle (such as a right angle or another angle) relative to the longitudinal axis LA1.

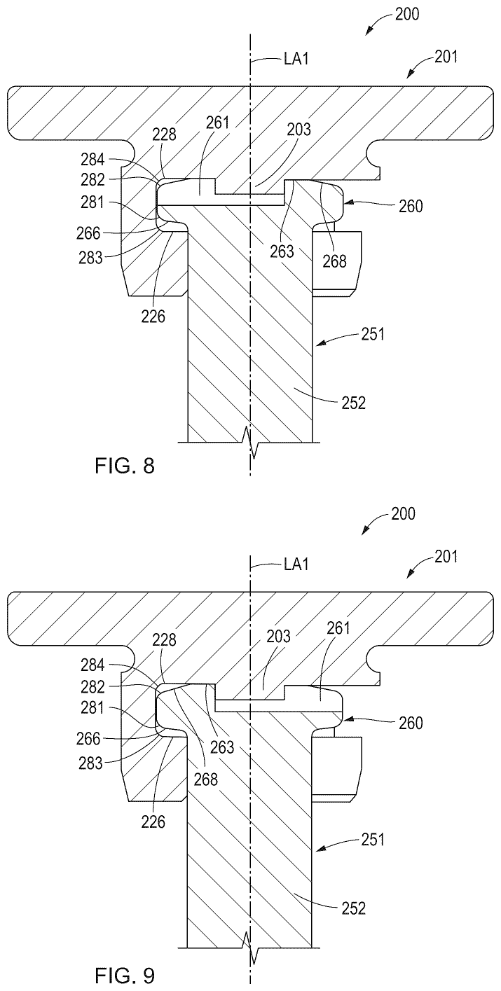

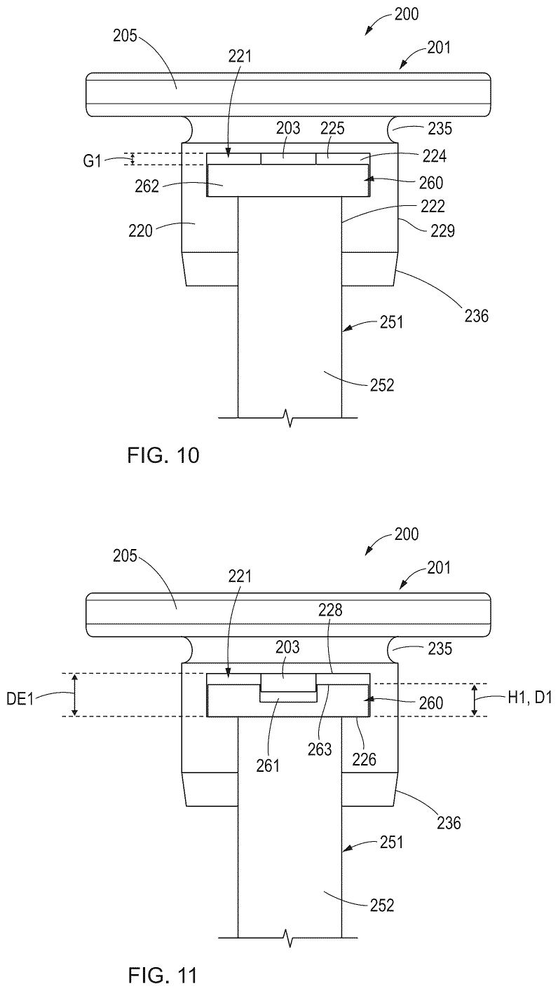

The tapered outer surface 266 of the head section 260 abuts against the first inner surface 226 when in the lowered position shown in FIGS. 4 and 5. The rod 251 can be suspended from the pad 201 when the lift pin 200 is in the lowered position shown in FIGS. 4 and 5. When in the raised position, the end face 263 of the rod 251 abuts against a second inner surface 228 of the sleeve section 220 of the pad 201. In one or more embodiments, the head section 260 includes a second tapered outer surface 268. The present disclosure contemplates that the taper of the second tapered outer surface 268 can be omitted such that an upper side of the head section 260 is planar (as shown in FIGS. 10 and 11) and spans the second tapered outer surface 268 shown in FIGS. 4 and 5. The planar upper side can reduce or eliminate tilting of the cap 201. In such an embodiment, the head section 260 can include the one or more curved edge surfaces 281, 282 shown in FIGS. 8 and 9 and the cap 201 can include the one or more curved corner surfaces 283, 284 shown in FIGS. 8 and 9. In such an embodiment, the tapered outer surface 266 can be used for the head section 260. The head section 260 of the rod 251 has a height H1, and the annular channel 225 of the pad opening 221 has a depth DE1 that is greater than the height H1 by a gap G1. The rod 251 is movable relative to the pad 201 within a movement range corresponding to the gap G1. The rod 251 is movable relative to the pad 201 along the longitudinal axis LA1. The gap G1 is a ratio of the height H1, and the ratio is at least 0.125. In one or more embodiments, the ratio is at least 0.15. In one or more embodiments, the gap G1 is at least 0.2 mm, such as at least 0.225 mm, for example at least 0.23 mm. The tapered outer surface 266 intersects the shaft section 252 at a distance D1 relative to the end face 263 of the head section 260. The depth DE1 can be greater than the distance D1 by the gap G1. FIGS. 4 and 5 show the rod 251 in a lower position at a lower end of the movement range. FIGS. 8 and 9 below show the rod 241 moved upwardly relative to the pad 201 at an upper position at an upper end of the movement range. In one or more embodiments, a contact area between the head section 260 and the pad 201 is reduced in the lower position than in the upper position. The reduced contact area facilitates reduced heat flow between the pad 201 and the rod 251 when the lift pin 200 is in the processing position.

Referring again to FIGS. 4 and 5, the pad 201 includes an opaque material, and the rod 251 is formed of a transparent material. The opaque material can include, for example, opaque quartz (e.g., white quartz, grey quartz, and/or black quartz), silicon carbide (SiC), and/or graphite coated with SiC. In one or more embodiments, the pad 201 is formed of graphite coated with SiC and the rod 251 is formed of transparent quartz and/or glassy carbon. In one or more embodiments, the substrate support 106 includes an outer surface formed of the opaque material, and the pad 201 includes an outer surface formed of the same opaque material. The pad 201 and/or the substrate support 106 have a thermal conductivity within a range of 100 Watts per meter-Kelvin (W/mK) to 250 W/mK. The pad 201 and/or the substrate support 106 have a coefficient of thermal expansion within a range of 4.0×10⁻⁶/Kelvin to 5.0×10⁻⁶/Kelvin, such as 4.3×10⁻⁶/Kelvin to 4.8×10⁻⁶/Kelvin. In one or more embodiments, the pad 201 has a thermal conductivity within a difference of 10% or less relative to a thermal conductivity of the substrate support 106. In one or more embodiments, the pad 201 has a coefficient of thermal expansion within a difference of 10% or less relative to a coefficient of thermal expansion of the substrate support 106.

The rod 251 has a lower thermal conductivity than the pad 201 and the substrate support 106. The rod 251 has a lower coefficient of thermal expansion than the pad 201 and the substrate support 106.

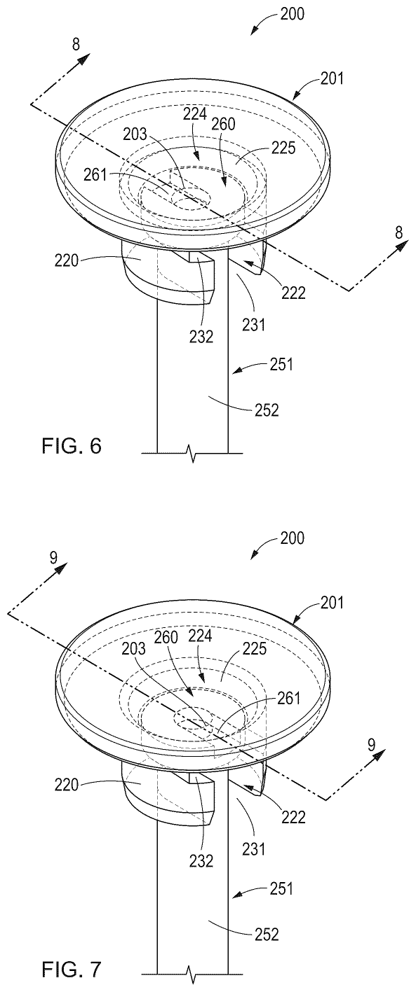

FIG. 6 is a schematic isometric view of the one of the lift pins 200 in the unlocked position shown in FIG. 4, according to one or more embodiments.

FIG. 7 is a schematic isometric view of the one of the lift pins 200 in the locked position shown in FIG. 5, according to one or more embodiments.

FIGS. 6 and 7 are described together. The head section 260 of the rod 251 is sized and shaped to slide (e.g., radially inwardly) into the second section 224 of the pad opening 221. The shaft section 252 of the rod 251 is sized and shaped to slide (e.g., radially inwardly) into the first section 222 of the pad opening 221. The first section 222 includes an outer portion 231 extending through a wall of the sleeve section 220, and the second section 224 includes an outer portion 232 extending through the wall of the sleeve section 220. In the unlocked position the rod opening 261 is at least partially azimuthally offset from the outer portions 231, 232 (as shown in FIG. 6), and in the locked position the rod opening 261 is azimuthally aligned with the outer portions 231, 232 (as shown in FIG. 7). In one or more embodiments, the rod 251 is moved from the unlocked position and to the locked position by rotating the rod 251 by more than 45 degrees, such as about 180 degrees.

FIG. 8 is a schematic side view of the one of the lift pins 200, along Section 8-8, in the unlocked position shown in FIG. 6, according to one or more embodiments.

FIG. 9 is a schematic side view of the one of the lift pins 200, along Section 9-9, in the locked position shown in FIG. 7, according to one or more embodiments.

FIGS. 8 and 9 are described together. FIGS. 8 and 9 show the lift pin 200 in the raised position such that the end face 263 abuts against the second inner surface 228. In the locked position shown in FIG. 9, the protrusion 203 of the pad 201 abuts against the head section 260 of the rod 251 to restrict or prevent the rod 251 from sliding radially outwardly out of the pad opening 221 and outside of the pad 201. The head section 260 can include one or more curved (e.g., rounded) edge surfaces 281, 282 (two are shown in FIGS. 8 and 9) and the cap 201 can include one or more curved (e.g., rounded) corner surfaces 283, 284. The one or more curved edge surfaces 281, 282 can have a radius of curvature that is substantially the same (e.g., within a difference of 10% or less) as a radius of curvature of the one or more curved corner surfaces 283, 284.

FIG. 10 is a schematic side view of one of the lift pins 200 shown in FIGS. 2 and 3 in an unlocked position, according to one or more embodiments.

FIG. 11 is a schematic side view of one of the lift pins 200 shown in FIG. 4 in a locked position, according to one or more embodiments.

FIGS. 10 and 11 are described together. In the implementation shown in FIGS. 10 and 11, the tapered outer surface 266 and the second tapered outer surface 268 are omitted from the head section 260.

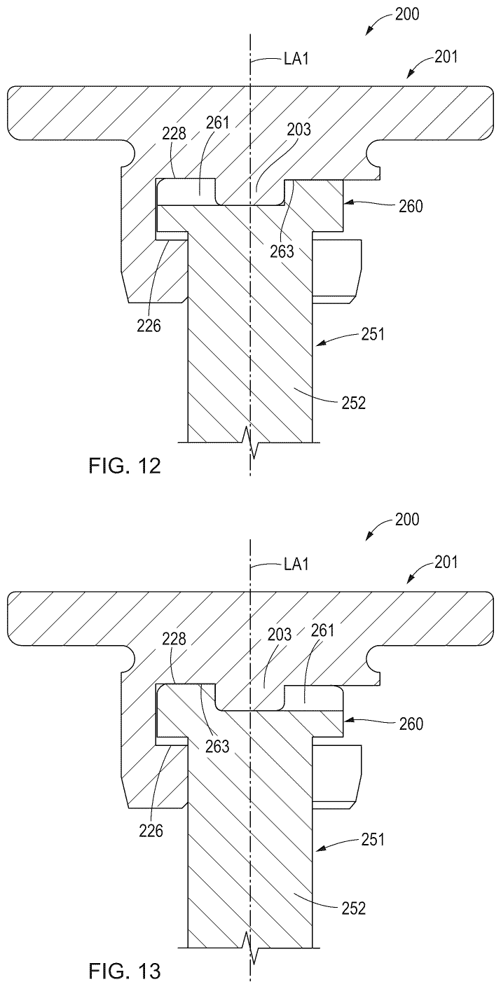

FIG. 12 is a schematic side view of the one of the lift pins 200 in the unlocked position shown in FIG. 10, according to one or more embodiments.

FIG. 13 is a schematic side view of the one of the lift pins 200 in the locked position shown in FIG. 11, according to one or more embodiments.

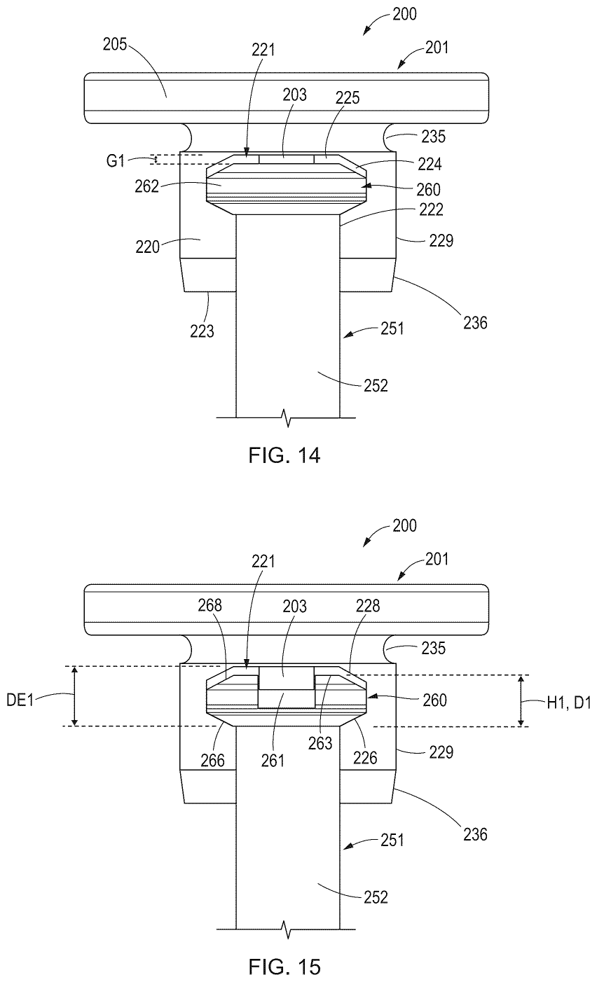

FIG. 14 is a schematic side view of one of the lift pins 200 shown in FIGS. 2 and 3 in an unlocked position, according to one or more embodiments.

FIG. 15 is a schematic side view of one of the lift pins 200 shown in the locked position shown in FIG. 14, according to one or more embodiments.

FIGS. 14 and 15 are described together. In the implementation shown in FIGS. 14 and 15, at least part of the first inner surface 226 and at least part of the second inner surface 228 are tapered. A taper angle of the first inner surface 226 can be the same as or different than the taper angle A1 of the tapered outer surface 266. A taper angle of the second inner surface 228 can be the same as or different than the taper angle of the second tapered outer surface 268.

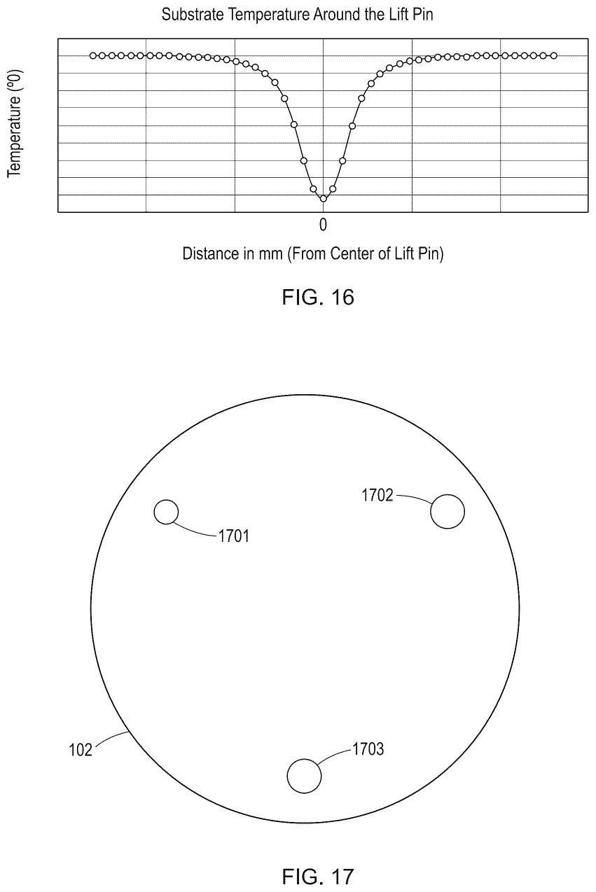

FIG. 16 is a schematic graph illustrating substrate temperature versus distance (in mm) for a substrate aligned above a lift pin according to a configuration other than those described herein. The distance is relative to a center of the lift pin. As shown in the graph, the temperature of a substrate region above the lift pin is different (shown, e.g., as lower) than the temperature of substrate regions around the lift pin.

It is believed that the subject matter described herein facilitates more uniform temperature across substrates (such as a more uniform temperature at regions above lift pins and other regions of the substrate, such as regions adjacent to the regions above the lift pins). It is also believed that the subject matter described herein facilitates more uniform film thickness for regions above lift pins (and other regions of the substrate, such as regions adjacent to the regions above the lift pins). Additionally, it is believed that site-front-least-squares-range (SFQR) can be reduced for regions above lift pins (and other regions of the substrate, such as regions adjacent to the regions above the lift pins). The reduced SFQR (e.g., substrate warpage) facilitate enhanced nanotopography and surface flatness for processed substrates.

FIG. 17 is a top graphical view of substrate film thickness according to a configuration other than those described herein. Three regions 1701-1703 of a processed substrate are shown which are vertically aligned above three lift pins. The three regions 1701-1703 have a different film thickness than other regions of the substrate 102.

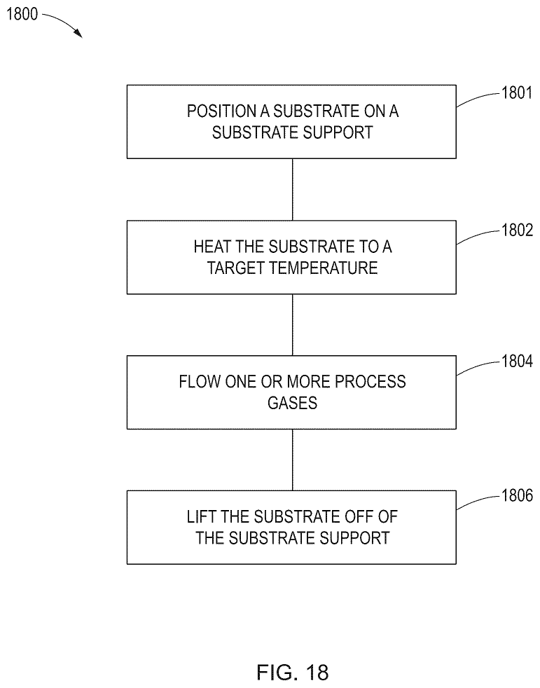

FIG. 18 is a schematic block diagram view of a method 1800 of substrate processing for semiconductor manufacturing, according to one or more embodiments.

Operation 1801 includes positioning a substrate on a substrate support in a processing volume of a processing chamber. In one or more embodiments, the positioning includes moving a substrate support and/or a plurality of lift pins relative to each other to land the substrate on the substrate support. In one or more embodiments, the positioning engages the pad 201 with the substrate support 106 and the rod 251 moves downwardly relative to the pad 201 such that the rod 251 is suspended from the pad 201. One or more of the lift pins include any of the lift pin 200 implementations described herein.

Operation 1802 of the method 1800 includes heating the substrate to a target temperature.

Operation 1804 includes flowing one or more process gases over the substrate to form one or more layers on the substrate.

Operation 1806 includes lifting the substrate off of the substrate support. In one or more embodiments, the lifting includes moving a substrate support and/or a plurality of lift pins relative to each other to engage the substrate with the lift pins and lift the substrate. In one or more embodiments, the lifting moves the rod 251 upwardly relative to the pad 201 such that the pad 201 is lifted off of the substrate support 106.

Benefits of the present disclosure include reduced temperature differences (e.g., temperature gradients) across substrate supports, reduced occurrences or hot spots and/or cold spots adjacent to lift pins, increased film thickness (e.g., increased growth rates), more uniform film deposition, more uniform film concentration (such as germanium concentration), enhanced nanotopography and surface flatness of process substrates, and reduced SFQR for substrates with film deposited thereon. Such benefits can be facilitated, for example, for regions above lift pins (and other regions of the substrate, such as regions adjacent to the regions above the lift pins). Such benefits can also be facilitated in a manner that reduces or eliminates chances of thermal shock of lift pins (and associated chances of defects, breakage, maintenance, and/or downtime), reduced or eliminated degradation of lift pins, and increased lifespans of lift pins. Benefits of the present disclosure also include reduced or eliminated lift pin rubbing, reduced or eliminated chances of substrate defects (such as scratching and/or particle accumulation), modularity of using higher and lower processing temperatures and heating powers, enhanced device performance (including at reduced structure sizes), reduced processing times, reduced delays, reduced downtime, increase device yield, and increased throughput.

As an example, using the gap G1 and/or the pad 201 and/or the rod 251 including tapered surfaces facilitate heating the pad 201 to a temperature similar to or equal than the temperature of the substrate support 106, with reduced heat transfer between the pad 201 and the rod 251. The locked position of the lift pin 200 facilitates such benefits while maintaining abutment between the pad 201 and the rod 251 during processing. During processing, contact between the pad 201 and the rod 251 is reduced while maintaining or increasing contact between the pad 201 and the substrate support 106. In between processing, contact between the pad 201 and the rod 251 is increased for stability and mechanical support. As another example, wearing of lift pins 200 and/or substrate supports 106 can be reduced or eliminated by facilitating more uniform heating during cleaning (e.g., etching) processing. As a further example, subject matter (such as the gap G1 and/or the tapered surfaces) can function as a thermal barrier between the pad 201 and the rod 251.

It is contemplated that one or more aspects disclosed herein may be combined. As an example, one or more aspects, features, components, operations and/or properties of the processing chamber 100, the substrate support 106, the lift pin 200 implementation shown in FIGS. 4-9, the lift pin 200 implementation shown in FIGS. 10-13, the lift pin 200 implementation shown in FIGS. 14 and 15, and/or the method 1800 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A lift pin for a processing chamber, comprising:
a rod comprising a shaft section and a head section, the head section comprising an opening formed in an outer edge of the head section and extending radially inwardly; and
a pad sized and shaped to fit at least partially around the head section of the rod such that the head section of the rod is movable relative to the pad within a movement range.

2. The lift pin of claim 1, wherein a contact area between the head section and the pad is reduced in a lower position of the movement range than in an upper position of the movement range.

3. The lift pin of claim 1, wherein the opening includes a slot extending into an end face of the head section of the rod.

4. The lift pin of claim 3, wherein the pad comprises a protrusion sized and shaped to protrude into the slot of the head section.

5. The lift pin of claim 1, wherein the pad comprises:
a head section; and
a sleeve section extending relative to a side of the head section, the sleeve section comprising a pad opening.

6. The lift pin of claim 5, wherein the pad opening comprises:
a first section formed in an end face of the sleeve section, wherein the shaft section of the rod is sized and shaped to slide into the first section of the pad opening;
a second section between the first section and the head section of the pad, the second section having a larger dimension than the first section, wherein the head section of the rod is sized and shaped to slide into the second section of the pad opening; and
the pad comprises a protrusion extending into the second section to define an annular channel at least partially about the protrusion.

7. The lift pin of claim 5, wherein:
the pad comprises a protrusion extending into a pad opening of the sleeve section to define an annular channel at least partially about the protrusion; and
the head section of the rod comprises a tapered outer surface sized and shaped to interface with an inner surface of the sleeve section.

8. The lift pin of claim 7, wherein the head section of the rod has a height, and the annular channel has a depth that is greater than the height by a gap.

9. The lift pin of claim 8, wherein the gap is a ratio of the height, and the ratio is at least 0.125.

10. A pad for a lift pin, the pad comprising:
a head section, and
a sleeve section extending relative to the head section, the sleeve section comprising a pad opening formed in an end face of the sleeve section, the pad opening extending radially inward into an outer face of the sleeve section.

11. The pad of claim 10, wherein the pad opening comprises:
a first section formed in the end face of the sleeve section;
a second section between the first section and the head section of the pad, the second section having a larger dimension than the first section.

12. The pad of claim 11, wherein the pad further comprises a protrusion extending into the second section to define an annular channel at least partially about the protrusion.

13. The pad of claim 11, wherein the first section includes an outer portion extending through a wall of the sleeve section.

14. The pad of claim 10, wherein the pad comprises an opaque material.

15. A processing chamber applicable for use in semiconductor manufacturing, comprising:
a substrate support disposed in a processing volume of the processing chamber;
a plurality of lift pins disposed at least partially through the substrate support, at least one of the plurality of lift pins comprising:
a pad comprising a pad opening formed in an end face of the pad, and
a rod disposed at least partially in the pad opening of the pad, the rod comprising a shaft section and a head section, the head section comprising an opening formed in an outer edge and an end face of the head section.

16. The processing chamber of claim 15, wherein the substrate support comprises an outer surface formed of an opaque material, the pad comprises an outer surface formed of the opaque material, and the rod is formed of a transparent material.

17. The processing chamber of claim 15, wherein the head section of the rod is movable relative to the pad within a movement range along a longitudinal axis of the rod.

18. The processing chamber of claim 17, wherein one or more of the pad or the rod are rotatable with respect to each other between an unlocked position and a locked position, and the one or more of the pad or the rod are rotatable in a plane oriented at an angle relative to the longitudinal axis.

19. The processing chamber of claim 15, wherein the pad comprises:
a head section; and
a sleeve section extending relative to the head section, wherein the pad opening is formed in the sleeve section.

20. The processing chamber of claim 19, wherein the pad opening comprises:
a first section formed in the end face;
a second section between the first section and the head section of the pad, the second section having a larger dimension than the first section; and
the pad comprises a protrusion extending into the second section to define an annular channel at least partially about the protrusion.
